(19) United States
(12) Patent Application Publication
(10) Pub. No.: US 2008/0224331 A1
(43) Pub. Date: Sep. 18, 2008

(54) ELECTRONIC DEVICE AND METHOD FOR MANUFACTURING THE SAME

(75) Inventor: Yuzo NEISHI, Suwa (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/046,726

(22) Filed: Mar. 12, 2008

(30) Foreign Application Priority Data
Mar. 14, 2007 (JP) 2007-064898

(51) Int. Cl. H01L 29/40; H01L 21/00

(52) U.S. Cl. 257/785; 438/121; 257/E23.078

(57) ABSTRACT

An electronic device includes: a semiconductor chip that includes an integrated circuit, a plurality of electrodes electrically connected to the integrated circuit, and a passivation film formed in a manner that at least a portion of each of the plurality of electrodes is exposed; a resin layer that is formed on the passivation film; a plurality of wirings, each of the plurality of wirings extending from a top surface of each of the plurality of electrodes to a top surface of the resin layer and electrically connected to each of the plurality of electrodes, respectively; a wiring substrate that has a wiring pattern opposing to and electrically connected to portions of the plurality of wirings above the resin layer; and a hardened adhesive resin that is placed between the semiconductor chip and the wiring substrate, wherein the adhesive resin internally has a residual stress that is generated by contraction at the time of hardening the adhesive resin, and a portion of the adhesive resin is disposed between a portion of the resin layer between adjacent ones of the wirings and the wiring substrate.

The entire disclosure of Japanese Patent Application No. 2007-064898, filed Mar. 14, 2007 is expressly incorporated by reference herein.

### BACKGROUND

1. Technical Field

The present invention relates to electronic devices and methods for manufacturing the same.

2. Related Art

A known semiconductor device is equipped with a resin layer formed on its active surface and wirings provided in a manner to extend from the surface of its electrode pads to the surface of the resin layer (see, for example, JP-A-2-272737). The resin layer and the wirings thereon form external terminals. When the semiconductor device having the plurality of wirings formed on the single resin layer is mounted on a motherboard, the entire resin layer may be pressed by the motherboard upon electrically connecting the plural wirings, and the integrated circuit formed on the semiconductor chip may be affected by the pressing force.

### SUMMARY

In accordance with an aspect of the present invention, it is possible to reduce influences that may be inflicted upon the integrated circuit after mounting.

(1) An electronic device in accordance with an embodiment of the invention includes: a semiconductor chip that includes an integrated circuit, a plurality of electrodes electrically connected to the integrated circuit, and a passivation film formed in a manner that at least a portion of each of the plurality of electrodes is exposed; a resin layer that is formed on the passivation film; a plurality of wirings, each of the plurality of wirings extending from a top surface of each of the plurality of electrodes to a top surface of the resin layer and electrically connected to each of the plurality of electrodes, respectively; a wiring substrate that has a wiring pattern opposing to and electrically connected to portions of the plurality of wirings above the resin layer; and a hardened adhesive resin that is placed between the semiconductor chip and the wiring substrate, wherein the adhesive resin internally has a residual stress that is generated by contraction at the time of hardening, and a portion of the adhesive resin is disposed between a portion of the resin layer between adjacent ones of the wirings and the wiring substrate.

According to the embodiment of the invention, the residual stress of the adhesive resin causes a contraction force in the portion between the resin layer and the wiring substrate between adjacent ones of the wirings, such that the external force applied to the integrated circuit can be reduced, and the influence on the integrated circuit can be reduced.

(2) In the electronic device, the top surface of the resin layer may be formed such that an area of the top surface that does not overlap the plurality of wirings becomes lower than an area of the top surface that overlaps the plurality of wirings.

(3) A method for manufacturing an electronic device in accordance with an embodiment of the invention includes the steps of:

preparing a semiconductor device having: a semiconductor chip including an integrated circuit, a plurality of electrodes electrically connected to the integrated circuit, and a passivation film formed in a manner that at least a portion of each of the electrodes is exposed; a resin layer formed on the passivation film; and a plurality of wirings electrically connected to the plurality of electrode, respectively, and extending from the top surfaces of the plurality of electrodes to the top surface of the resin layer;

placing the semiconductor device onto a wiring substrate having a wiring pattern through a thermosetting type adhesive resin precursor; and

applying a pressure force and heat between the semiconductor device and the wiring substrate,

wherein the applying of the pressure force and heat includes electrically connecting the plurality of wirings on the resin layer to the wiring pattern, wherein the pressure force is applied such that the portion of the resin layer between adjacent ones of the wirings does not contact the wiring substrate, a portion of the adhesive resin precursor is disposed on the portion of the resin layer between the adjacent ones of the wirings, and the adhesive resin precursor is hardened and contracted by the heat.

According to the embodiment of the invention, the portion of the resin layer between adjacent ones of the wirings is not allowed to contact the wiring substrate, such that the influence on the integrated circuit caused by an external force can be reduced. Also, the residual stress of the hardened and contracted adhesive resin causes a contraction force in the portion between the resin layer and the wiring substrate, such that the external force applied to the integrated circuit can be reduced, and the influence on the integrated circuit can be reduced.

In the method for manufacturing an electronic device, the preparing of the semiconductor device may include forming the plurality of wirings on the resin layer, and etching portions of the resin layer between adjacent ones of the wirings, wherein a portion of the resin layer that does not overlap the plurality of wirings may be made lower by the etching than a portion of the resin layer that overlaps the plurality of wirings.

### BRIEF DESCRIPTION OF THE DRAWINGS

FIG. 1 is a plan view of a semiconductor device to be used in an electronic device in accordance with an embodiment of the invention.

FIG. 2 is a cross-sectional view of the semiconductor device taken along lines II-II shown in FIG. 1.

FIG. 3 is a cross-sectional view of the semiconductor device taken along lines III-III shown in FIG. 1.

FIGS. 4A and 4B are cross-sectional views for describing a method for manufacturing an electronic device in accordance with an embodiment of the invention.

FIGS. 5A and 5B are cross-sectional views of an electronic device in accordance with an embodiment of the invention.

### DESCRIPTION OF EXEMPLARY EMBODIMENTS

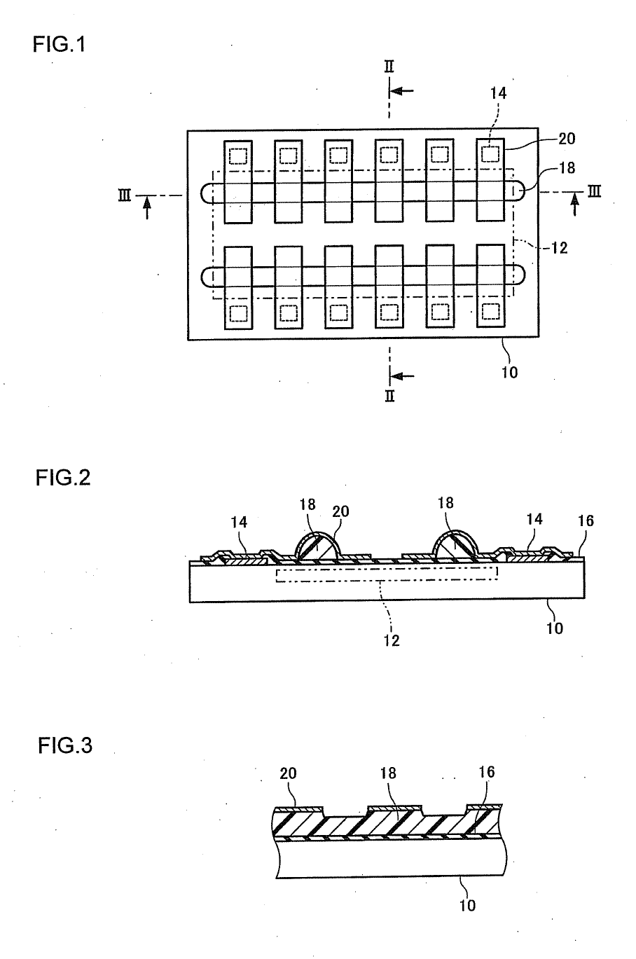

FIG. 1 is a plan view of a semiconductor device used for an electronic device in accordance with an embodiment of the invention. FIG. 2 is a cross-sectional view of the semiconductor device taken along lines II-II shown in FIG. 1. FIG. 3 is a cross-sectional view of the semiconductor device taken along lines III-III shown in FIG. 1.

The semiconductor device includes a semiconductor chip 10. An integrated circuit (transistors and the like) is formed in the semiconductor chip 10. The semiconductor chip 10 has electrodes 14 that are electrically connected to the integrated circuit 12 through internal wirings (not shown). The semiconductor chip 10 has an elongated shape in one direction (having a rectangular plane configuration), and a plurality of the electrodes 14 are arranged along the long sides of the semiconductor chip 10. A passivation film 16, which exposes at least a potion of the electrodes 14, is formed on the semiconductor chip 10. The passivation film 16 may be formed only from an inorganic material, such as, SiO₂, SiN or the like. The passivation film 16 is formed above the integrated circuit 12.

Resin layers 18 are formed on the passivation film 16. The electrodes 14 are formed in the end sections of the semiconductor chip 10, and the resin layers 18 are formed in a central area more inside than the electrodes 14. As the material of the resin layers 18, for example, polyimide resin, silicon modified polyimide resin, epoxy resin, silicon modified epoxy resin, benzocyclobutene (BCB), polybenzoxazole (PBO), phenol system resin and the like may be used.

A plurality of wirings 20 are formed, extending from the top surfaces of the plurality of electrodes 14 to the top surface of the resin layers 18, respectively. The wirings 20 are electrically connected to the electrodes 14, and formed on the resin layer 18. The wirings 20 extend from the top surfaces of the electrodes 14, run over the passivation film 16, and reach the top surfaces of the resin layers 18. The wirings 20 are electrically connected to the electrodes 14 on the top surfaces of the electrodes 14. The wirings 20 and the electrodes 14 may be in direct contact with one another, or conductive films (not shown) may be provided between the two. The wirings 20 are formed in a manner to extend over the end sections of the resin layers 18 on the opposite side of the electrodes 14 and reach the top surface of the passivation film 16. The wirings 20 extend from the electrodes 14 disposed at the end sections of the semiconductor chip 10 toward the central area thereof.

The top surface of the resin layers 18 is formed in a manner that areas of the top surface that does not overlap the plurality of wirings 20 are lower than areas of the top surface that overlaps the plurality of wirings 20 (see FIG. 3). After the plurality of wirings 20 have been formed on the resin layer 18, portions of the resin layer 18 between adjacent ones of the wirings 20 may be etched.

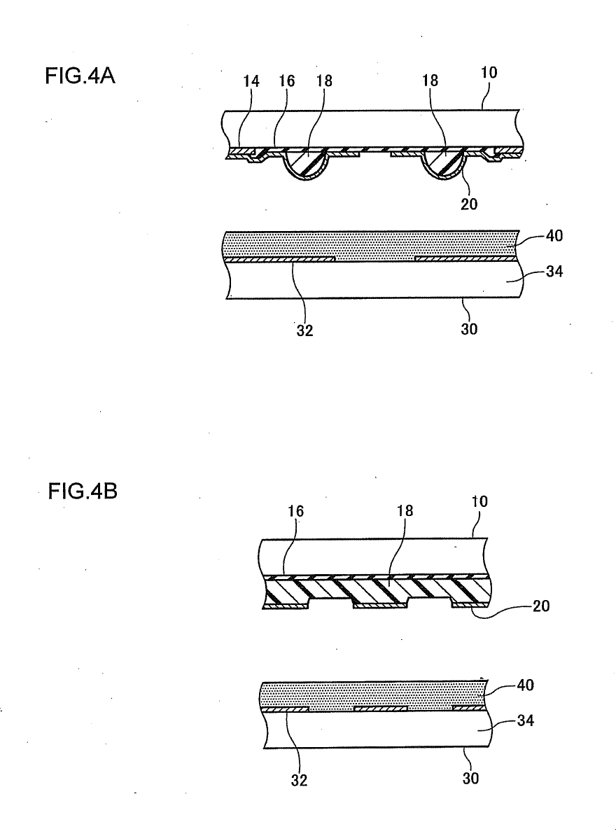

FIGS. 4A and 4B are cross-sectional views for describing a method for manufacturing an electronic device in accordance with an embodiment of the invention. The view of the semiconductor device shown in FIG. 4A corresponds to the cross-sectional view (FIG. 2) taken along the lines II-II of FIG. 1, and the view of the semiconductor device shown in FIG. 4B corresponds to the cross-sectional view (FIG. 3) taken along the lines III-III of FIG. 1.

According to the present embodiment, the semiconductor device described above is disposed, through a thermosetting type adhesive resin precursor 40, on a wiring substrate 30 having a wiring pattern 32. The wiring substrate 30 may be a liquid crystal panel or an organic EL panel. A substrate 34 that supports the wiring pattern 32 may be composed of glass or resin. Anisotropic conductive material in which conductive particles are dispersed in the adhesive resin precursor 40 may be used. Then, pressure force and heat are applied to an area between the semiconductor device and the wiring substrate 30. The pressure force is applied to the extent that the plurality of wirings 20 on the resin layer 18 electrically contact the wiring pattern 32, but portions (surface portions) of the resin layer 18 between adjacent ones of the wirings 20 do not contact the wiring substrate 30. By this, the surface (contact surface) of the resin layer 18 that overlaps the wirings 20 reacts to an external force, but the surface (non-contact surface) of the resin layer 18 that does not overlap the wirings 20 does not react to an external force. As the area that reacts to external forces becomes smaller, the region of the integrated circuit that may be affected by the influence of external forces becomes smaller. Moreover, the adhesive resin precursor 40 is disposed on the resin layers 18 between adjacent ones of the wirings 20, and hardened and contracted by heat. The pressure force applied is maintained until the adhesive resin precursor 40 hardens. When the adhesive resin precursor 40 hardens, the pressure force is removed. In this manner, the electronic device is manufactured.

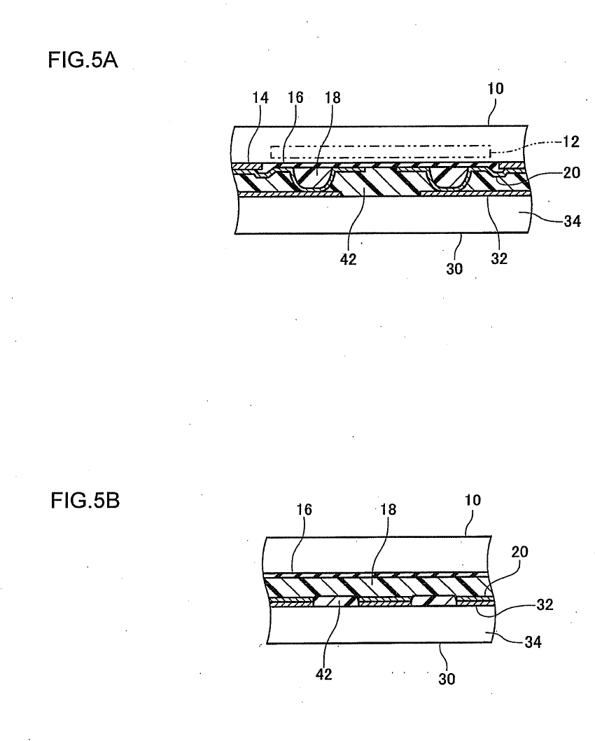

FIGS. 5A and 5B are cross-sectional views for describing an electronic device in accordance with an embodiment of the invention. The view of the semiconductor device shown in FIG. 5A corresponds to the cross-sectional view (FIG. 2) taken along the lines II-II of FIG. 1, and the view of the semiconductor device shown in FIG. 5B corresponds to the cross-sectional view (FIG. 3) taken along the lines III-III of FIG. 1.

The electronic device includes the semiconductor device (having a semiconductor chip 10, resin layers 18 and a plurality of wirings 20) described above, and a wiring substrate 30 having a wiring pattern 32 provided opposing to and electrically connected to portions of the plural wirings 20 above the resin layer 18. Hardened adhesive resin 42 is present between the semiconductor chip 10 and the wiring substrate 30. The adhesive resin 42 internally has a residual stress that is generated by its contraction occurring when it hardens. Portions of the adhesive resin 42 are disposed between portions of the resin layer 18 between adjacent ones of the wirings 20 and the wiring substrate 30. According to the present embodiment, the residual stress of the adhesive resin 42 causes a contraction force in the portion between the resin layer 18 and the wiring substrate 30 between adjacent ones of the wirings 20, such that the external force applied to the integrated circuit 12 can be reduced, and the influence on the integrated circuit 12 can be reduced.

The invention is not limited to the embodiments described above, and many modifications can be made. For example, the invention may include compositions that are substantially the same as the compositions described in the embodiments (for example, a composition with the same function, method and result, or a composition with the same objects and result). Also, the invention includes compositions in which portions not essential in the compositions described in the embodiments are replaced with others. Also, the invention includes compositions that achieve the same functions and effects or achieve the same objects of those of the compositions described in the embodiments. Furthermore, the invention includes compositions that include publicly known technology added to the compositions described in the embodiments.

What is claimed is:

1. An electronic device comprising:
a semiconductor chip that includes an integrated circuit, a plurality of electrodes electrically connected to the integrated circuit, and a passivation film formed in a manner that at least a portion of each of the plurality of electrodes is exposed;
a resin layer that is formed on the passivation film;
a plurality of wirings, each of the plurality of wirings extending from a top surface of each of the plurality of electrodes to a top surface of the resin layer and electrically connected to each of the plurality of electrodes, respectively;
a wiring substrate that has a wiring pattern opposing to and electrically connected to portions of the plurality of wirings above the resin layer; and
a hardened adhesive resin that is placed between the semiconductor chip and the wiring substrate,
wherein the adhesive resin internally has a residual stress that is generated by contraction occurring at the time of hardening, and a portion of the adhesive resin is disposed between a portion of the resin layer between adjacent ones of the wirings and the wiring substrate.

2. An electronic device according to claim 1, wherein the top surface of the resin layer is formed such that an area of the top surface that does not overlap the plurality of wirings becomes lower than an area of the top surface that overlaps the plurality of wirings.

3. A method for manufacturing an electronic device, the method comprising the steps of:
preparing a semiconductor device having a semiconductor chip including an integrated circuit, a plurality of electrodes electrically connected to the integrated circuit, and a passivation film formed in a manner that at least a portion of each of the electrodes is exposed, a resin layer formed on the passivation film, and a plurality of wirings electrically connected to the plurality of electrode, respectively, and extending from the top surfaces of the plurality of electrodes to the top surface of the resin layer;
placing the semiconductor device onto a wiring substrate having a wiring pattern through a thermosetting type adhesive resin precursor; and
applying a pressure force and heat between the semiconductor device and the wiring substrate,
wherein the applying of the pressure force and heat includes electrically connecting the plurality of wirings on the resin layer to the wiring pattern, wherein the pressure force is applied such that the portion of the resin layer between adjacent ones of the wirings does not contact the wiring substrate, a portion of the adhesive resin precursor is disposed on the portion of the resin layer between the adjacent ones of the wirings, and the adhesive resin precursor is hardened and contracted by the heat.

4. A method for manufacturing an electronic device according to claim 3, wherein the preparing of the semiconductor device includes forming the plurality of wirings on the resin layer, and etching portions of the resin layer between adjacent ones of the wirings, wherein a portion of the resin layer that does not overlap the plurality of wirings is made by the etching to be lower than a portion of the resin layer that overlaps the plurality of wirings.
